(19) United States
(12) Patent Application Publication
(10) Pub. No.: US 2008/0006602 A1
(43) Pub. Date: Jan. 10, 2008

(54) Apparatus and method for fabricating color filter

(75) Inventor: Chun-Pin Huang, Miao-Li (TW)

Correspondence Address: WEI TE CHUNG;FOXCONN INTERNATIONAL, INC., 1650 MEMOREX DRIVE, SANTA CLARA, CA, 95050, US

(73) Assignee: INNOLUX DISPLAY CORP.

(21) Appl. No.: 11/825,984

(22) Filed: Jul. 9, 2007

(30) Foreign Application Priority Data
Jul. 7, 2006 (TW) 95124900

(51) Int. Cl. C23C 14/22; B05B 7/24; B05D 5/06

(52) U.S. Cl. 216/12; 118/313; 118/315; 204/192.1; 427/162

(57) ABSTRACT

An exemplary coating apparatus (40) for fabricating a color filter (3) includes a supporting table (44) and a dispenser (48). The supporting table supports a substrate (30) that serves as a foundation of the color filter. The dispenser includes plural first nozzles (412) for spraying a first color photo-resist onto the substrate, plural second nozzles (422) for spraying a second color photo-resist onto the substrate, and plural third nozzles (432) for spraying a third color photo-resist onto the substrate. The first, second and third nozzles simultaneously spray the first, second and third color photo-resists onto respective different locations on the substrate. Therefore three corresponding color resins can be formed on the substrate in a single coating step. Thus, a cost of fabricating the color filter is reduced.

### FIELD OF THE INVENTION

The present invention relates to apparatuses and methods for fabricating color filters of liquid crystal display (LCD) devices, and particularly to a coating apparatus including three kinds of nozzles which can fabricate color resins having three different colors in one step.

### GENERAL BACKGROUND

In general, a monochrome or a color LCD device has the advantages of thinness, low weight, and low power consumption. For this reason, LCD devices are widely used in various types of electronic equipment, from pocket calculators to large-scale office automation equipment.

Conventionally, a color LCD device includes a color filter positioned opposite to a liquid crystal layer. The color filter includes a black matrix having a plurality of apertures, and three kinds of color resins filled in the apertures. The color resins are typically red, green and blue (RGB) color resins. The clarity and quality of images displayed by the LCD device depend in large part upon the characteristics of the black matrix of the color filter.

The basic structure of a typical color filter is shown in FIG. 8. The color filter 1 includes a transparent substrate 10 with a black matrix 11 deposited thereon. The black matrix 11 defines a plurality of apertures (not labeled) therein. RGB color resins 12 are filled in the apertures of the black matrix 11 in a sequential, repeating pattern. The RGB color resins 12 filter light beams passing therethrough, thus producing respective RGB color light beams. A transparent protecting layer 13 is provided on the color resins 12. A transparent electrode layer 14 is provided on the transparent protecting layer 13.

The black matrix 11 functions as a light-shielding mask, to improve the contrast ratio of an LCD device using the color filter 1. In particular, the black matrix 11 increases the OD (Optical Density, i.e. light-shielding) value of the color filter 1. The black matrix 11 also reduces optical reflection at top and bottom surfaces thereof, by absorbing most or even all light that is incident on such surfaces.

Referring to FIG. 9, a method for fabricating the color filter 1 includes the following steps: providing the transparent substrate 10 (step S1); forming the black matrix 11 on the transparent substrate 10 (step S2), the black matrix 11 defining a plurality of apertures therein; coating a first color photo-resist layer on the transparent substrate 10 with the black matrix 11 (step S3); exposing and developing the first color photo-resist layer to form first color resins (step S4); coating a second color photo-resist layer on the transparent substrate 10 with the black matrix 11 and the first color resins (step S5); exposing and developing the second color photo-resist layer to form second color resins (step S6); coating a third color photo-resist layer on the transparent substrate 10 with the black matrix 11 and the first and second color resins (step S7); exposing and developing the third color photo-resist layer to form third color resins (step S8); forming the transparent protecting layer 13 on all the color resins 12 (step S9); and forming the transparent electrode layer 14 on the transparent protecting layer 13 (step S10).

Referring to FIG. 10, a photo-resist coating apparatus 20 employed in the above method for fabricating the color filter 1 is shown. The coating apparatus 20 includes a supporting table 21 and a dispenser 22. The supporting table 21 can move relative to the dispenser 22. The supporting table 21 includes a supporting surface 211, which is configured to support the transparent substrate 10.

Referring also to FIG. 11, the dispenser 22 is long and narrow, and is connected to a photo-resist container (not shown). The dispenser 22 includes a bottom outlet slit 222. The dispenser 22 is disposed above the supporting table 21, with the outlet slit 222 facing the supporting surface 211. In operation, the transparent substrate 10 with the black matrix 21 is placed on the supporting surface 211, the supporting table 21 slides horizontally relative to the dispenser 22, and the dispenser 22 sprays photo-resist through the outlet slit 222 onto the transparent substrate 10. Thereby, the photo-resist is uniformly coated on the transparent substrate 10.

However, the method for fabricating the color filter 1 includes three photo-resist coating steps, three exposing steps and three developing steps. Therefore the method is rather complicated and may be considered somewhat inefficient. Furthermore, three photo-resist coating apparatuses 20 are needed, for coating the three color photo-resist layers respectively. Therefore the method is quite costly.

Thus, a new photo-resist coating apparatus that can overcome the above-described problems is desired. A method employing such a coating apparatus for fabricating a color filter is also desired.

### SUMMARY

In one preferred embodiment, a coating apparatus for fabricating a color filter includes a supporting table and a dispenser. The supporting table is configured for supporting a substrate that serves as a foundation of a color filter. The dispenser includes at least one first nozzle configured for spraying a first color photo-resist onto the substrate, at least one second nozzle configured for spraying a second color photo-resist onto the substrate, and at least one third nozzle configured for spraying a third color photo-resist onto the substrate. The at least one first, second and third nozzles simultaneously spray the first, second and third photo-resists onto respective different locations on the substrate.

Other novel features and advantages will become more apparent from the following detailed description when taken in conjunction with the accompanying drawings.

### BRIEF DESCRIPTION OF THE DRAWINGS

FIG. 1 is an isometric, partly abbreviated view of a coating apparatus according to a first embodiment of the present invention, the coating apparatus including a dispenser and a supporting table, and showing a color filter on the supporting table.

FIG. 2 is an enlarged, isometric, inverted view of the dispenser of the coating apparatus of FIG. 1.

FIG. 3 is a schematic, side cross-sectional view of part of a color filter fabricated according to any of various exemplary embodiments of the present invention.

FIG. 4 is a flowchart summarizing an exemplary method for fabricating the color filter of FIG. 3.

FIG. 5 is an isometric view of a dispenser of a coating apparatus according to a second embodiment of the present invention.

FIG. 6 is an isometric, inverted view of the dispenser of FIG. 5.

FIG. 7 is a schematic, side view showing operation of the dispenser of FIG. 5 in fabricating the color filter of FIG. 3.

FIG. 8 is a schematic, side cross-sectional view of part of a conventional color filter.

FIG. 9 is a flowchart summarizing a conventional method for fabricating the color filter of FIG. 8.

FIG. 10 is a schematic, side view showing a photo-resist coating apparatus employed in fabricating the color filter of FIG. 8 according to the method of FIG. 9, the coating apparatus including a dispenser and a supporting table.

FIG. 11 is an enlarged, isometric, inverted view of the dispenser of FIG. 10.

### DETAILED DESCRIPTION OF PREFERRED EMBODIMENTS

Referring to FIG. 1, a coating apparatus 40 according to a first embodiment of the present invention is shown. The coating apparatus 40 includes a dispenser 48, a supporting table 44, and two supporting frames 45. The supporting frames 45 are fixed in position at two opposite sides of the supporting table 44 respectively. The dispenser 48 is mounted between the supporting frames 45, and is located above the supporting table 44. The supporting table 44 can move relative to the supporting frames 45 and the dispenser 48.

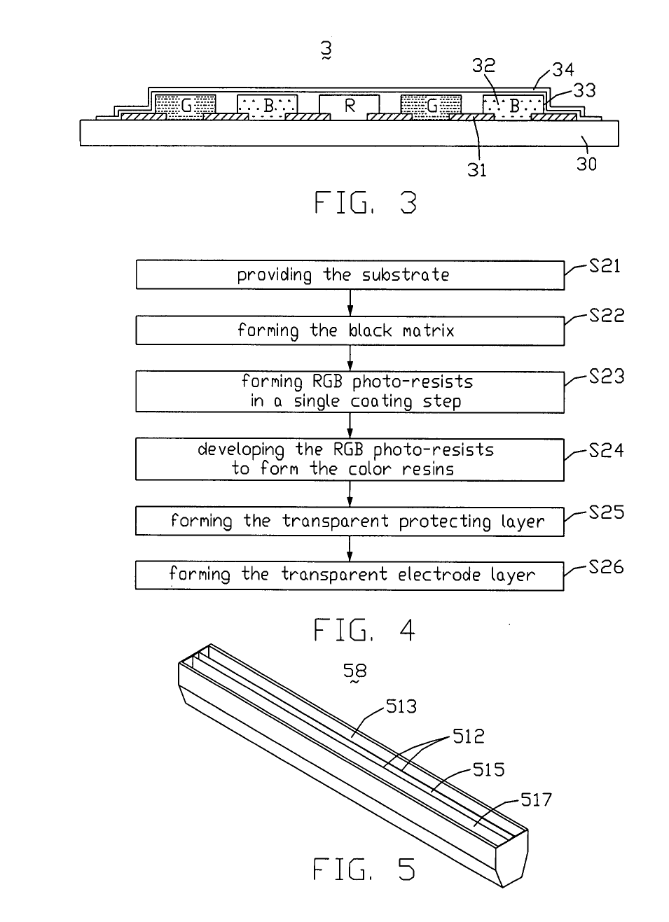

Referring also to FIG. 3, the supporting table 44 includes a supporting surface 441 configured for supporting a substrate 30. The substrate 30 is the foundation of a color filter 3 that is eventually fabricated. When the supporting table 44 slides horizontally relative to the supporting frames 45 and the dispenser 48, a vertical distance between the dispenser 48 and the supporting surface 441 is constant.

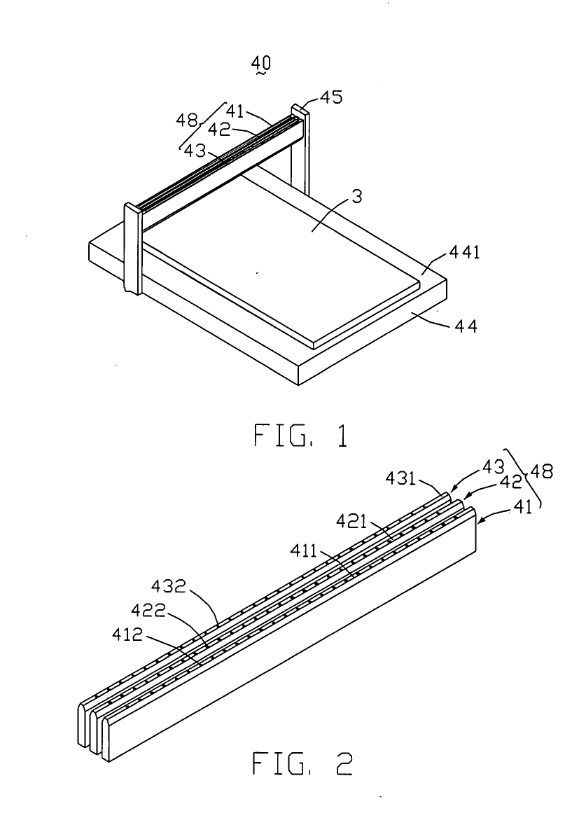

Referring also to FIG. 2, the dispenser 48 includes a first nozzle unit 41, a second nozzle unit 42, and a third nozzle unit 43. The first, second and third nozzle units 41, 42, 43 are long and narrow, and are parallel to one another. The first, second and third nozzle units 41, 42, 43 are respectively connected to a first photo-resist container (not visible), a second photo-resist container (not visible), and a third photo-resist container (not visible). The first nozzle unit 41 includes a first spraying surface 411. The first spraying surface 411 is parallel to the supporting surface 441, and has a plurality of first nozzles 412 formed thereat. The first nozzles 412 are arranged in a line, and a pitch between adjacent first nozzles 412 is constant. The second nozzle unit 42 includes a second spraying surface 421. The second spraying surface 421 is parallel to the supporting surface 441, and has a plurality of second nozzles 422 formed thereat. The second nozzles 422 are arranged in a line, and a pitch between adjacent second nozzles 422 is constant. The third nozzle unit 43 includes a third spraying surface 431. The third spraying surface 431 is parallel to the supporting surface 441, and has a plurality of third nozzles 432 formed thereat. The third nozzles 432 are arranged in a line, and a pitch between adjacent third nozzles 432 is constant.

The first, second and third nozzles 412, 422, 432 are rectangular. The pitch between adjacent first nozzles 412 is the same as the pitch between adjacent second nozzles 422, and is the same as the pitch between adjacent third nozzles 432. Along a lengthwise direction of the three nozzle units 41, 42, 43, the first, second and third nozzles 412, 422, 432 are alternately arranged. That is, the first, second and third nozzles 412, 422, 432 are staggered relative to one another.

The first photo-resist container stores red photo-resist. The second photo-resist container stores green photo-resist. The third photo-resist container stores blue photo-resist. That is, the first, second and third nozzle units 41, 42, 43 are respectively configured to form red, green, and blue resins of the color filter 3.

Referring to FIG. 3, the color filter 3 includes the substrate 30 with a black matrix 31 deposited thereon. The black matrix 31 defines a plurality of apertures (not labeled) therein. Color resins 32 are filled in the apertures of the black matrix 31. The color resins 32 include the red, green and blue resins arranged in a sequential, repeating pattern. A transparent protecting layer 33 is provided on the color resins 32. A transparent electrode layer 34 is provided on the transparent protecting layer 33.

Referring to FIG. 4, an exemplary method employing the coating apparatus 40 for fabricating the color filter 3 includes: providing the substrate 30 (step S21); forming the black matrix 31 (step S22); forming RGB photo-resists in a single coating step (step S23); developing the RGB photo-resists to form the color resins 32 (step S24); forming the transparent protecting layer 33 (step S25); and forming the transparent electrode layer 34 (step S26).

In step S21, the substrate 30 is provided. The substrate 30 is generally made from a transparent material, such as glass. Typically, the substrate 30 is made from low-alkali glass or non-alkali glass.

In step S22, the black matrix 31 is formed. First, the substrate 30 is cleaned. A uniform black resin layer is formed on the substrate 30 by a spin coating method or a spinless coating method. The black resin layer can be photosensitive resin. The black resin layer is dried and soft baked. Ultraviolet light is used to expose the black resin layer through a photo-mask. Then the exposed black resin layer is developed to form the black matrix 31 having the apertures. The substrate 30 with the black matrix 31 is hard baked to remove residual developing solution and cleaning solution. In an alternative embodiment, a positive photo-resist layer is coated on a CrOx/Cr (chromium oxide/chromium) film. The photo-resist layer is exposed to ultraviolet light and is then developed. Then the CrOx/Cr film is etched using the developed photo-resist layer as a mask to form the black matrix 31. When a CrOx film is used, x is typically 1.5 or 2.5.

In step S23, the color resins 32 are formed in a single coating step. The substrate 30 with the black matrix 31 is placed on the supporting table 44 of the coating apparatus 40. The supporting table 44 moves relative to the nozzle units 41, 42, 43, and the first, second and third nozzles 412, 422, 432 respectively spray red, green and blue photo-resist onto the substrate 30. The RGB photo-resists are formed as color strips arranged in a sequential repeating pattern.

In step S24, the RGB photo-resists are exposed to form the color resins 32. In this embodiment, the color resins 32 are strip-shaped color resins 32. If island color resins 32 are required, further exposing and developing steps are needed.

In step S25, the transparent protecting layer 33 is formed on the color resins 32. This can for example be done by a spin coating method or a spray coating method.

In step S26, the transparent electrode layer 34 is formed on the transparent protecting layer 33 by a sputtering method. The transparent electrode layer 34 can be made from indium tin oxide (ITO) or indium zinc oxide (IZO). Thus, the color filter 3 is formed.

Because the coating apparatus 40 includes the three nozzle units 41, 42, 43 parallel to one another, and the three nozzle units 41, 42, 43 can spray red, green and blue photo-resist respectively, the RGB color resins 32 can be formed in one coating step. Thus, a cost of fabricating the color filter 3 is reduced.

Referring to FIG. 5, a dispenser 58 of a coating apparatus according to a second embodiment of the present invention is similar in principle to the dispenser 48 of the coating apparatus 40. However, the dispenser 58 is a single body, and includes a first photo-resist container 513, a second photo-resist container 515, and a third photo-resist container 517. The three photo-resist containers 513, 515, 517 are isolated from each other by two partitions 512. The first, second and third photo-resist containers 513, 515, 517 respectively contain red, green and blue photo-resist.

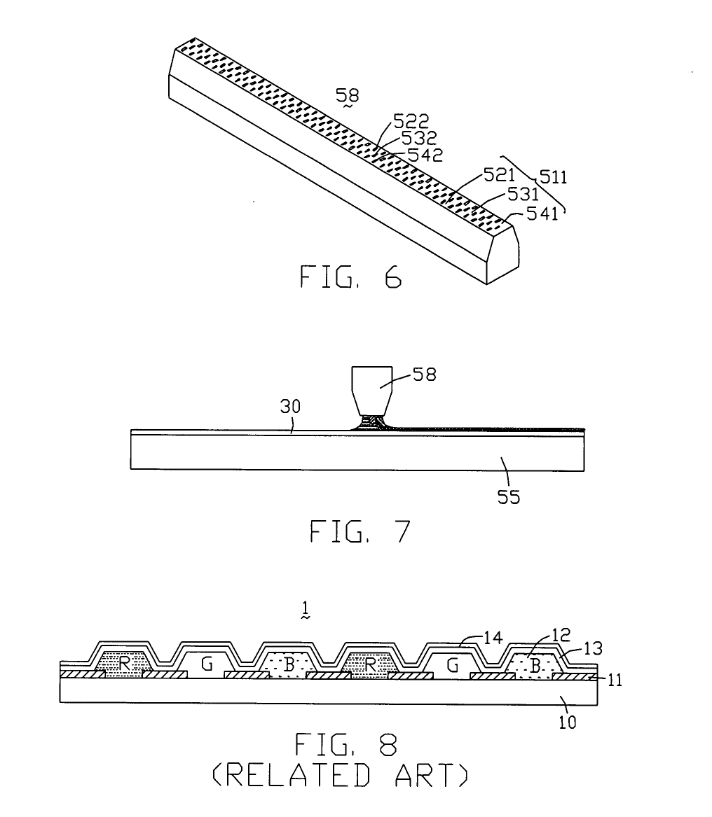

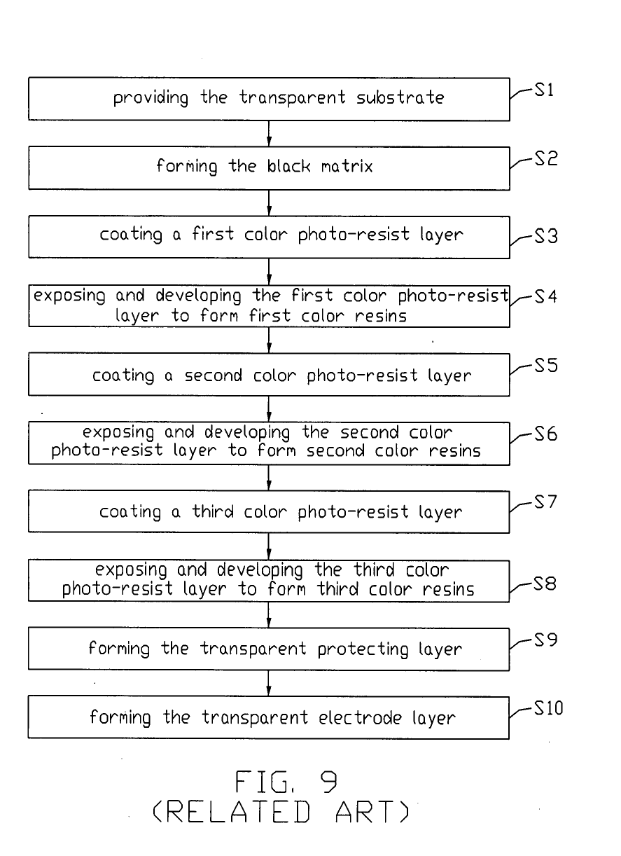

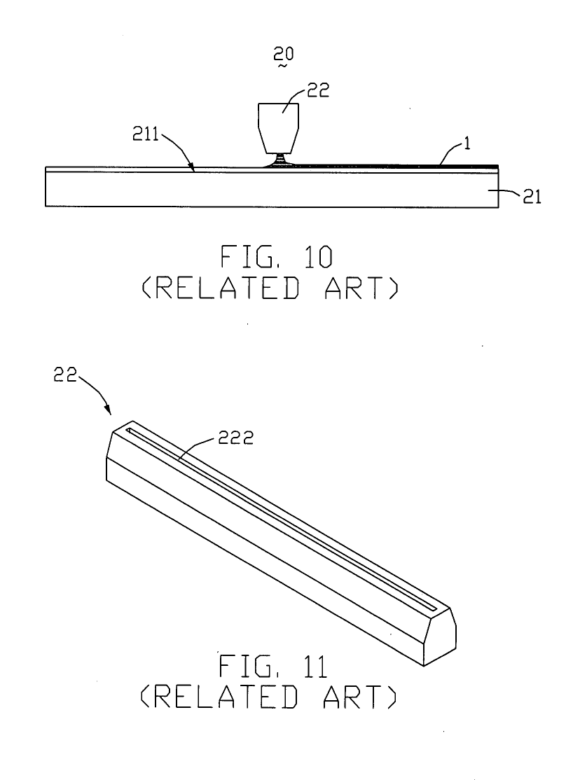

Referring also to FIG. 6, the dispenser 58 also includes a spraying surface 511. The spraying surface 511 is divided into an elongate first spraying part 521, an elongate second spraying part 531, and an elongate third spraying part 541, which respectively correspond to the first, second and third photo-resist containers 513, 515, 517. The first spraying part 521 has a plurality of first nozzles 522, which are arranged in a line and spaced apart from each other at a constant pitch. The second spraying part 531 has a plurality of second nozzles 532, which are arranged in a line and spaced apart from each other at a constant pitch. The third spraying part 541 has a plurality of third nozzles 542, which are arranged in a line and spaced apart from each other at a constant pitch. The first, second and third nozzles 522, 532, 542 are rectangular, and have a same size. The pitch between adjacent first nozzles 522 is the same as the pitch between adjacent second nozzles 532, and is the same as the pitch between adjacent third nozzles 542. Along a lengthwise direction of the nozzle unit 58, the first, second and third nozzles 522, 532, 542 are alternately arranged. That is, the first, second and third nozzles 522, 532, 542 are staggered relative to one another. The first, second and third nozzles 522, 532, 542 are respectively connected to the first, second and third photo-resist containers 513, 515, 517.

Referring to FIG. 7, operation of the dispenser 58 in fabricating the color filter 3 is shown. The substrate 30 is supported on a corresponding supporting table 55. When the dispenser 58 is working, the first nozzles 522 spray a red photo-resist, the second nozzles 532 spray a green photo-resist, and the third nozzles 542 spray a blue photo-resist. Then the RGB photo-resists are developed. By using the coating apparatus of the second embodiment, the color resins 32 of the color filter 3 can be formed in a single step.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A coating apparatus for fabricating a color filter, comprising:
a supporting table configured for supporting a substrate that serves as a foundation of a color filter; and
a dispenser comprising at least one first nozzle configured for spraying a first color photo-resist onto the substrate, at least one second nozzle configured for spraying a second color photo-resist onto the substrate, and at least one third nozzle configured for spraying a third color photo-resist onto the substrate;
wherein the at least one first, second and third nozzles are arranged to simultaneously spray the first, second and third color photo-resists onto respective different locations on the substrate.

2. The coating apparatus as claimed in claim 1, wherein the dispenser further comprises a first photo-resist container connected with the at least one first nozzle, a second photo-resist container connected with the at least one second nozzle, and a third photo-resist container connected with the at least one third nozzle.

3. The coating apparatus as claimed in claim 1, wherein the dispenser further comprises a nozzle unit, and the nozzle unit comprises a spraying surface having the at least one first, second and third nozzles formed thereat.

4. The coating apparatus as claimed in claim 1, wherein the dispenser comprises a first nozzle unit, a second nozzle unit, and a third nozzle unit, which are parallel to one another.

5. The coating apparatus as claimed in claim 4, wherein the first nozzle unit comprises a first spraying surface having the at least one first nozzle formed thereat, the second nozzle unit comprises a second spraying surface having the at least one second nozzle formed thereat, and the third nozzle unit comprises a third spraying surface having the at least one third nozzle formed thereat.

6. The coating apparatus as claimed in claim 1, wherein the at least one first, second and third nozzles are rectangular, and have a same size.

7. The coating apparatus as claimed in claim 1, further comprising two supporting frames respectively mounted at two opposite sides of the supporting table, the supporting frames holding the dispenser above the supporting table.

8. The coating apparatus as claimed in claim 1, wherein the at least one first, second and third nozzles are staggered relative to one another.

9. The coating apparatus as claimed in claim 1, wherein the first, second and third color photo-resists are red photo-resist, green photo-resist, and blue photo-resist respectively.

10. A method for fabricating a color filter, the method comprising:
providing a substrate;
forming a black matrix on the substrate, the black matrix defining a plurality of apertures;
providing a coating apparatus, the coating apparatus comprising a supporting table and a dispenser, the dispenser comprising at least one first nozzle, at least one second nozzle, and at least one third nozzle;
placing the substrate with the black matrix on the supporting table;
simultaneously coating first, second and third color photo-resists on the substrate in respective apertures of the black matrix by using the at least one first, second and third nozzles respectively; and
developing the first, second and third color photo-resists to form color resins having three different colors.

11. The method as claimed in claim 10, further comprising forming a transparent protecting layer on the color resins.

12. The method as claimed in claim 11, further comprising forming a transparent electrode layer on the transparent protecting layer.

13. The method as claimed in claim 12, wherein the transparent electrode layer is made from indium tin oxide or indium zinc oxide, and is formed by a sputtering method.

14. The method as claimed in claim 10, wherein the first, second and third color photo-resists are arranged in a sequential repeating pattern on the substrate.

15. The method as claimed in claim 10, wherein the substrate is made from low-alkali glass or non-alkali glass.

16. The method as claimed in claim 10, wherein forming the black matrix comprises:
forming a photosensitive black resin layer on the substrate;
drying and soft baking the black resin layer;
exposing the black resin layer to ultraviolet light; and
developing the black resin layer to form the black matrix.

17. The method as claimed in claim 16, further comprising hard baking the substrate having the black matrix formed thereon.

18. The method as claimed in claim 10, wherein forming the black matrix comprises:
forming a CrOx/Cr film on the substrate;
coating a positive photo-resist layer on the CrOx/Cr film;
exposing and developing the positive photo-resist layer; and
etching the CrOx/Cr film using the developed photo-resist layer as a mask to form the black matrix.

19. The method as claimed in claim 10, wherein the first, second and third color photo-resists are red photo-resist, green photo-resist, and blue photo-resist respectively.

20. A coating apparatus for fabricating a color filter, comprising:
a supporting table configured for supporting a substrate that serves as a foundation of a color filter; and
a dispenser comprising a plurality of first nozzles configured for spraying a first color photo-resist onto the substrate, a plurality of second nozzles configured for spraying a second color photo-resist onto the substrate, and a plurality of third nozzles configured for spraying a third color photo-resist onto the substrate, wherein the first nozzles are arranged in a first line, the second nozzles are arranged in a second line, the third nozzles are arranged in a third line, the first, second and third lines are adjacent to each other and parallel to each other, the first nozzles are staggered relative to the second nozzles, the first nozzles are also staggered relative to the third nozzles, and the second nozzles are staggered relative to the third nozzles.
